(19) United States
(12) Patent Application Publication
(10) Pub. No.: US 2025/0054929 A1
(43) Pub. Date: Feb. 13, 2025

(54) OPTICAL ENGINE FOR HIGH-SPEED DATA TRANSMISSION

(71) Applicant: SAMTEC, INC., New Albany, IN (US)

(72) Inventors: Marc EPITAUX, Grand-Rue (CH); John CORONATI, Colorado Springs, CO (US)

(21) Appl. No.: 18/722,873

(22) PCT Filed: Dec. 22, 2022
(86) PCT No.: PCT/US2022/082209

§ 371 Date: Jun. 21, 2024

Related U.S. Application Data
(60) Provisional application No. 63/292,518, filed on Dec. 22, 2021.

(51) Int. Cl. H01L 25/16; G02B 6/42; H01L 23/00; H01L 23/44; H01L 23/498

(52) U.S. Cl. CPC H01L 25/167; G02B 6/4251; G02B 6/4268; G02B 6/4274; H01L 23/44; H01L 23/49822; H01L 23/49838; H01L 23/562; H01L 24/16; H01L 2224/16227; H01L 2924/1426

(57) ABSTRACT

An optical engine having an optically transparent substrate with a lens on a first major surface and an optoelectronic element on an opposed second major surface is described. The optical engine has a sealed optical path and is capable of operating submerged in a cooling liquid. The optical engine may be attached to a mounting substrate to form an optoelectronic subassembly that may be incorporated in many different types of optical interconnects.

### CROSS-REFERENCE TO RELATED APPLICATIONS

This claims priority to U.S. Patent Application Ser. No. 63/292,518 filed Dec. 22, 2021, the disclosure of which is hereby incorporated by reference as if set forth in its entirety herein.

### BACKGROUND

Optical communication channels, using modulated light signals, may be used to rapidly and reliably transmit information in a variety of applications such as fiber optic communication networks or computer systems.

Optical fiber optic networks have advantages over other types of networks such as electrically conductive cable-based networks. Many existing electrically conductive cable networks operate at near maximum possible data transmission rates and at near maximum possible distances for copper wire cable technology. Fiber optic networks may be used to reliably transmit data at higher rates over further distances than is possible with copper cable networks.

Computer systems employing high speed optical interconnects may provide improved performance when compared to other computers systems. The performance of some computer systems can be restricted by the rate that computer processors can access memory or communicate with other components in the computer system. The restriction can be due, in part, to the physical limitations of data interconnects such as electrical connections. For example, electrical pins with a particular size and/or surface area that may be used in electrical connections may only be capable of transmitting a specific amount of data, and in turn this may limit the maximum bandwidth for data signals. In some circumstances, such connections may result in bottlenecks when the maximum bandwidth of connections becomes a performance limiting factor. High speed optical interconnects using light signals may permit transmission of information at increased data rates to decrease or eliminate such bottlenecks.

Although modulated light signals may be used to transmit data at increased data rates in fiber optic networks, computer systems or other applications, almost all memory, switching, and processing components of such systems use electrical signals. Accordingly, optoelectronic assemblies may be used to convert electrical signals to optical signals, convert optical signals to electrical signals, or convert both electrical signals to optical signals and optical signals to electrical signals. A key component of an optoelectronic assembly is an optical engine, which provides optical-to-electrical and/or electrical-to-optical conversion in high-speed communication systems. Optical engines may include a microcontroller that controls operation of the optical engine. The optical engine may be part of an optoelectronic subassembly that in turn is part of an optoelectronic assembly or an optical interconnect module. The optoelectronic subassembly may incorporate an optical engine in a package having an electrical, mechanical and/or thermal interface that is more easily integrated into a computer or communication system. The optoelectronic assembly may incorporate an optical engine or optoelectronic subassembly in a package having an optical interface more easily integrated into a computer or communication system, such as for example, either detachable or permanent optical fibers in optical alignment with the optical engine. An optical interconnect module may also have desirable electrical, mechanical, thermal, and optical interface properties and may be consider equivalent to an optoelectronic assembly. Examples of optoelectronic assemblies and optical interconnect modules include packages compliant with multi-source agreement standards such as QSFP, QSFP-DD, OSFP, COBO, and many others.

An optical engine or an optical engine integrated into any of these higher level packages may be configured as a transmitter, a receiver, or a transceiver. In a transmitter, the optical engine converts electrical signals received from an electrical component into optical signals. In a receiver, the optical engine converts optical signal into electrical signals that are transmitted to an electrical component. In a transceiver, the optical engine both converts electrical signals into optical signals and converts optical signals into electrical signals.

As the bandwidth and channel density of high-speed communication systems has increased, there is a need for improvements in optical engines to support higher data transfer rates, to decrease the optical engine size, and to provide an optical engine that is easily integrated with other communication system components.

### SUMMARY

In one aspect of the present disclosure, an optical engine is described. The optical engine has an optically transparent substrate having a first major surface and an opposed second opposed major surface. An optoelectronic element configured to emit or receive light through the transparent substrate is mounted on the second major surface of the transparent substrate. The optoelectronic element has an associated electrical component, which is in electrical communication with the optoelectronic element and is configured to deliver or receive high-speed electrical signals to or from the optoelectronic element. A microcontroller may be mounted on the first major surface of the transparent substrate and is in electrical communication with the associated electrical component. In some embodiments, the optoelectronic element may be a photonic integrated circuit.

In another aspect of the present disclosure, an optoelectronic subassembly is described. The optoelectronic subassembly includes an optical engine having an optically transparent substrate with a first major surface and an opposed second major surface. The optical engine includes an optoelectronic element attached to the second major surface of the transparent substrate, which is configured to emit or receive light through the transparent substrate. The optoelectronic subassembly further includes a mounting substrate having a first major surface, an opposed second major surface, and may include a hole in the first major surface. The second major surface of the transparent substrate may be attached to an attachment area of the first major surface of the mounting substrate and the optoelectronic element resides in the hole in the first major surface of the mounting substrate.

### BRIEF DESCRIPTION OF THE DRAWINGS

The foregoing summary, as well as the following detailed description of illustrative embodiments of the intervertebral implant of the present application, will be better understood when read in conjunction with the appended drawings. For the purposes of examples of the present disclosure, there is shown in the drawings illustrative embodiments. It should be understood, however, that the application is not limited to the precise arrangements and instrumentalities shown. In the drawings:

FIG. 1 is an exploded perspective view of an optical engine according to an embodiment of the current invention;

FIG. 2 is a top perspective view of the optical engine of FIG. 1, shown assembled, illustrating a first major surface of the optical engine, and optoelectronic elements and associated electrical components mounted to the first major surface;

FIG. 3 is a bottom perspective view of the optical engine of FIG. 2, showing a second major surface of the optical engine, and optoelectronic elements and associated electrical components mounted to the second major surface;

FIG. 4 is a schematic cross-sectional view of a portion of an optical engine of FIG. 1;

FIG. 5 is a bottom plan view of the optical engine of FIG. 1, with optoelectronic elements and associated electrical components removed;

FIG. 6 is a perspective view of a lens array configured to be mounted to the first major surface of the optical engine according to one example;

FIG. 7 is an enlarged schematic cross-sectional view of a portion of the optical engine of FIG. 1, showing the lens array of FIG. 6 mounted to the first major surface of the optical engine, and associated optical paths in the optical engine;

FIG. 8 is an exploded perspective view of an optoelectronic subassembly including the optical engine of FIG. 1 configured to be mounted to a mounting substrate 400 in one example;

FIG. 9 is a perspective view of the optoelectronic subassembly of FIG. 8;

FIG. 10 is a schematic cross-sectional view of an interface between the mounting substrate and the optical engine of FIG. 8 in one example;

FIG. 11 is a schematic cross-sectional view of an interface between the mounting substrate and the optical engine of FIG. 8 in another example; and

FIG. 12 shows a perspective view of an optoelectronic element of the optical engine of FIG. 1, configured as a photonic integrated circuit optoelectronic element in one example.

### DETAILED DESCRIPTION

The present disclosure can be understood more readily by reference to the following detailed description taken in connection with the accompanying figures and examples, which form a part of this disclosure. It is to be understood that this disclosure is not limited to the specific devices, methods, applications, conditions or parameters described and/or shown herein, and that the terminology used herein is for the purpose of describing particular embodiments by way of example only and is not intended to be limiting of the scope of the present disclosure. Also, as used herein, the singular forms “a,” “an,” and “the” include “at least one” and a plurality. Further, reference to a plurality as used in the specification including the appended claims includes the singular “a,” “an,” “one,” and “the,” and further includes “at least one.” Further still, reference to a particular numerical value in the specification including the appended claims includes at least that particular value, unless the context clearly dictates otherwise.

The term “plurality”, as used herein, means more than one. When a range of values is expressed, another example includes from the one particular value and/or to the other particular value. Similarly, when values are expressed as approximations, by use of the antecedent “about,” it will be understood that the particular value forms another example. All ranges are inclusive and combinable.

The term “substantially,” “approximately,” and derivatives thereof, and words of similar import, when used to described sizes, shapes, spatial relationships, distances, directions, and other similar parameters includes the stated parameter in addition to a range up to 10% more and up to 10% less than the stated parameter, including up to 5% more and up to 5% less, including up to 3% more and up to 3% less, including up to 1% more and up to 1% less.

It should be noted that the illustrations and discussions of the embodiments and examples shown in the figures are for exemplary purposes only and should not be construed limiting the disclosure. One skilled in the art will appreciate that the present disclosure contemplates a range of possible modifications of the various aspects, embodiments and examples described herein. Additionally, it should be understood that the concepts described above with the above-described embodiments and examples may be employed alone or in combination with any of the other embodiments and examples described above. It should further be appreciated that the various alternatives described above with respect to one illustrated embodiment can apply to all other embodiments and examples described herein, unless otherwise indicated. Reference is therefore made to the claims.

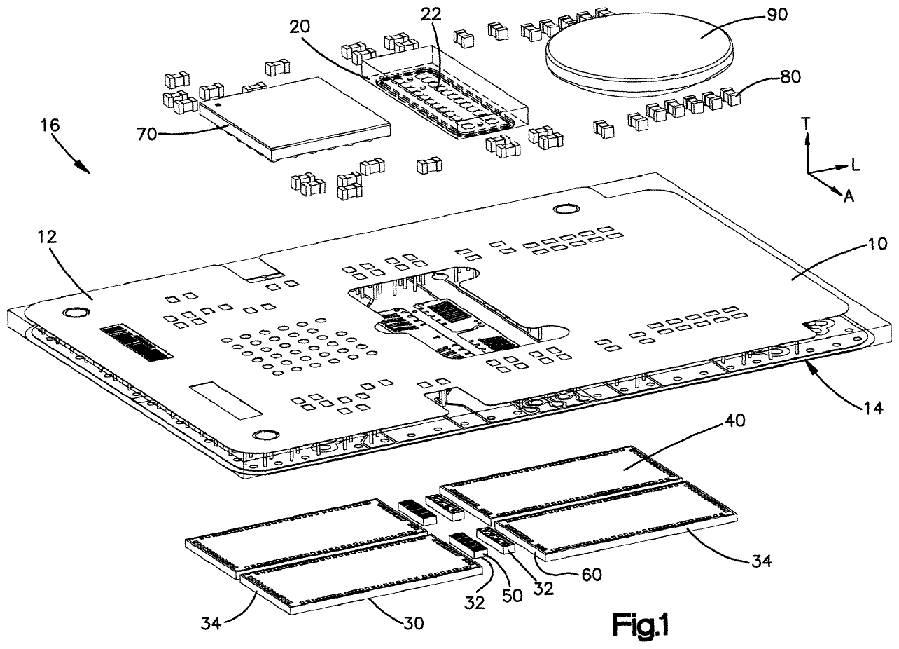

Referring initially to FIGS. 1-3 generally, an optical engine 16 includes an engine substrate that carries optoelectrical and associated electrical components. In one example, the engine substrate can be configured as an optically transparent substrate 10 having a first major surface 12 and a second major surface 14 that is opposite the first major surface 12 along a transverse direction (T). The first major surface 12 and second major surface 14 generally lie in respective first and second planes that are each defined by a longitudinal direction (L) that is perpendicular to the transverse direction (T), and a lateral direction (A) that is perpendicular to each of the transverse direction (T) and the longitudinal direction (L). The first and second planes are therefore offset from each other in the transverse direction (T). The first major surface 12 can be said to be disposed above, or upward, with respect to the second major surface 14. Similarly, the second major surface 14 can be said to be disposed below, or downward, with respect to the first major surface 12. Thus, an upward direction can be defined as a direction from the second major surface 14 to the first major surface 12 along the transverse direction (T). Similarly, a downward direction can be defined as a direction from the first major surface 12 to the second major surface 14 along the transverse direction (T). It is appreciated that these relative directional descriptors apply even though the first major surface 12 may not, in fact, be located above the second major surface 14 during use, depending on the position and orientation of the optically transparent substrate 10 during use.

The optically transparent substrate 10 is preferably formed from glass, but may be a transparent crystal, such as sapphire, silicon, or a transparent organic substrate. Inorganic substrates may be preferred since they generally have better thermo-mechanical stability and a better coefficient of thermal expansion match to semiconductor elements and components mounted on the substrates.

It is well known that different materials have different transmission properties at different electromagnetic wavelengths. For example, sapphire has a wide transmission range for electromagnetic radiation wavelengths of between approximately 200 nm to 4,000 nm, which is a wider range than most glasses. Optical engines generally work over a very small wavelength window, for example, less than 50 nm and in many cases a much smaller window. The term transparent substrate as used herein means that the substrate is transparent at an electromagnetic wavelength corresponding to an operating wavelength of the optical engine 16. Common operating wavelengths are 850 nm, 920 nm, 13010 nm and 1553 nm, but the optical engine 16 can operate at any wavelength within the transparency range of the substrate.

The optical engine 16 can include at least one first electrical component and/or at least one first optoelectronic element mounted on the first major surface 12. For instance, the optical engine 16 can include a plurality of first electrical components and/or first optoelectronic elements mounted on the first major surface 12. In one example, the optical 16 engine can include a microcontroller 70 and passive electrical components 80 may be mounted on the first major surface 12. Similarly, the optical engine 16 can include at least one second electrical component and/or at least one second optoelectronic element mounted on the second major surface 14. For instance, the optical engine 16 can include a plurality of second electrical components and/or second optoelectronic elements mounted on the second major surface 14. For example, the optical engine 16 can include an optoelectronic element 32 and an associated electrical component 34 both mounted on the second major surface 14. FIG. 1 shows the optical engine 16 having four (4) optoelectronics elements 32 and four (4) associated electrical components 34 configured to be mounted to the second major surface 14, but it should be appreciated that the optical engine 16 can have more or fewer optoelectronic elements 32 and associated electrical components 34 as desired. In other examples, all electrical and optoelectronic components may be mounted on the second major surface 14 of the optically transparent substrate 10. In some embodiments, the microcontroller 70 may be omitted, which can allow for the optically transparent substrate 10 to have a smaller footprint defined along a direction perpendicular to the transverse direction (T).

The associated electrical component 34 is in electrical communication with the optoelectronic element 32 and is configured to deliver or receive high-speed electrical signals to or from the optoelectronic element. In one example, the optical engine 16 can be a transmitter, whereby the optoelectronic element 32 may be a transmit (Tx) optoelectronic element such as a light source, which can be configured as a laser 50 that produces optical signals corresponding to input electrical signals. In another example, the optical engine 16 can be a receiver, whereby the optoelectronic element 32 may be a receive (Rx) optoelectronic element such as a photodetector 60 that produces electrical signals corresponding to input optical signals. In other examples, the optical engine 16 can be a transceiver, and thus can include the transmit (Tx) optoelectronic element 32 configured as the light source, and a receive (Rx) optoelectronic element configured as the photodetector 60. It will thus be appreciated that the optical engine 16 can include at least one optoelectronic element 32 that is configured to perform an optoelectronic conversion. For The optoelectronic conversion can be a conversion of optical signals to electrical signals, or a conversion of electrical signals to optical signals.

When the light source is configured as the laser 50, the laser 50 may be a multi-transverse mode laser, that oscillates on a plurality of transverse modes or it may be a single-transverse mode laser that oscillates on a single transverse mode. The laser 50 may be an array of lasers, such as an array of vertical cavity, surface emitting lasers (VCSELs) formed on a monolithic die. The VCSELs may be directly modulated by modulating their drive current to produce a modulated optical signal. When the optical engine 16 includes the Tx optoelectronic element 32 such as the light source or laser 50, then the associated Tx electrical component 34 is a laser driver 30. The laser driver 30 can define a light modulation protocol that determines the modulation of the light emitted from the light source or laser 50 based on the electrical signals received from the electrical component, to output optical signals that correspond to input electrical signals from the electrical component.

The photodetector 60 may be configured as an array of photodetectors that are configured to convert input optical signals to corresponding electrical signals that correspond to the input optical signals. The array of photodetectors 60 can be formed on a monolithic die. If the optical engine 16 includes the Rx optoelectronic element 32, for instance configured as a photodetector 60, then the optical engine 16 can include an associated Rx electrical component 34 defined as a current-to-voltage converter. The current-to-voltage converter can be configured as a transimpedance amplifier (TIA) 40. The TIA 40 can be configured to receive the electrical signals from the photodetectors 60, condition the electrical signals, and output the conditioned electrical signals, for instance to an electrical component. In one example, the TIA 40 amplifies the electrical signals to voltage levels that are usable for communication with the electrical component. Thus, the electrical signals output by the TIA 40 can be the electronic equivalent of the optical signals received by the photodetectors 60. Thus, the electrical signals output by the TIA 40 can mimic the patterns of the input optical signals.

It should be appreciated that in examples whereby the optical engine 16 is a transceiver, then the optical engine 16 can include the associated Tx electrical component 34 in the form of the laser driver 30 as described above, and the optical engine 16 can further include the associated Rx electrical component 34 in the form of the current-to-voltage converter which can be configured as a transimpedance amplifier (TIA) 40 as described above. It can thus be said that the optical engine 16 can include at least one optoelectronic component 32 and at least one associated electrical component 34.

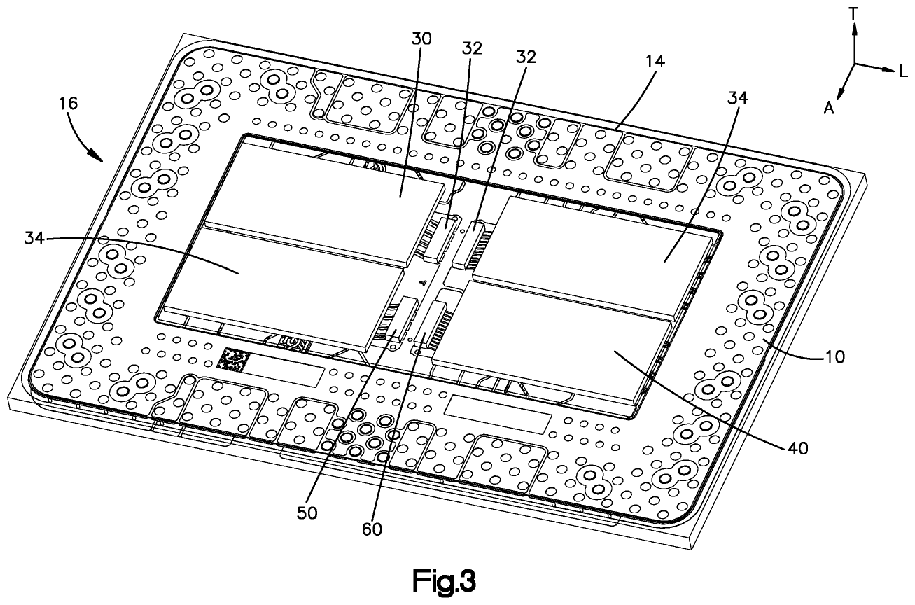

Both the at least one optoelectronic element 32 and its associated electrical component 34 may be flip-chip mounted to second surface contact pads situated on the second major surface 14 (see FIG. 3). The optoelectronic element 32 is in electrical communication with its associated electrical element 34 through conductive traces that terminate on the second surface contact pads to which the optoelectronic element 32 and its associated electrical component are attached. The associated electrical component 34 is situated adjacent to the optoelectronic element 32 so as to minimize a length and an inductance of the electrically conductive traces that run between the optoelectronic element 32 and its associated electrical component 34. Minimizing the length and the inductance of the electrically conductive traces between the optoelectronic element 32 and its associated electrical component 34 helps to increase the signal integrity of high-speed electrical signals.

In some examples, the differential electrical signals can travel at high-speed data transfer rates while producing no more than 6% asynchronous worst-case, multi-active cross-talk. The data transfer rate can be greater than or equal to approximately 1 gigabit per second, such as greater than or equal to approximately 5 gigabits per second, such as greater than or equal to approximately 10 gigabits per second, such as greater than or equal to approximately 20 gigabits per second, such as such as greater than or equal to approximately 28 gigabits per second, such as greater than or equal to approximately 56 gigabits per second. In other examples, the electrical signals can travel at data transfer rates equal to or greater than approximately 100 megabits per second producing no more than 6% worst-case, multi-active cross-talk.

The optical engine can further include a lens 20 that may be mounted on the first major surface 12. As is described in more detail below, the lens 20 may be a lens array 22 having a plurality of individual lens 21 formed on a monolithic substrate. The lens 20 is in optical alignment with the Tx optoelectronic element 32, which can be configured as a light source as described above. As shown at FIG. 7, during operation, light emitted by the light source, which can be configured as a laser, may be directed through the optically transparent substrate 10 into the lens 20. Light emerging from the lens 20 may be substantially collimated and directed substantially in the transverse direction (T), perpendicular to the first major surface 12. If the optoelectronic element 32 is a photodetector 60, the lens 20 may focus incoming light through the optically transparent substrate 10 on to the photodetector 60. Incoming light entering the lens 20 may be substantially collimated and directed substantially in the transverse direction (T), perpendicular to the first major surface 12.

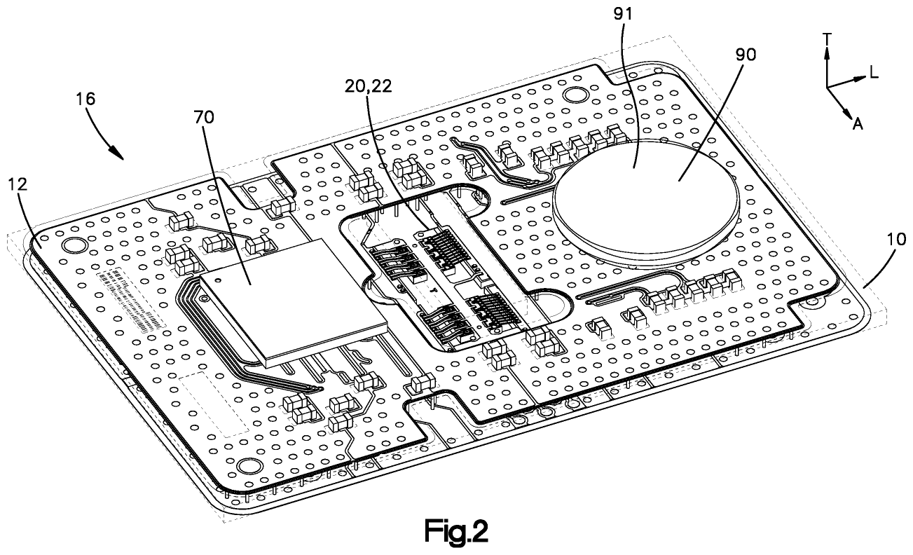

Referring again to FIGS. 1-2, the optical engine 16 can further include a mechanical guard 90 that is mounted to the first major surface 12 of the optically transparent substrate 10. The mechanical guard 90 can include an uppermost surface 91 that is spaced in the upward direction from the first major surface 12 in the transverse direction (T) a greater distance than the distance that the uppermost surfaces of any of the passive components 80 are spaced in the upward direction from the first major surface 12. Thus, the mechanical guard 90 helps protect the passive components 80 from mechanical damage associated with incorporating the optical engine 16 into an optoelectronic assembly, especially an optoelectronic assembly having detachable optical fibers. In some examples, the mechanical guard 90 serves no electrical or optical function.

The optoelectronic element 32, the associated electrical component 34, and the microcontroller 70 may be flip-chip mounted to the optically transparent substrate 10. The flip-chip mounting may take many forms such use of a ball grid array, an electrically conductive adhesive, copper pillars, or stud bumps, but other forms of flip-chip mounting may be used. A semiconductor element that is mounted on a substrate so that a face of the semiconductor element having an electrical or optical circuit adjacent the mounting substrate may be considered to be flip-chip mounted.

FIG. 2 shows a top perspective view of the optical engine 16 depicted in FIG. 1 with all the components mounted to the first major surface 12. The microcontroller 70, lens 20, and mechanical guard 90 may be positioned at different locations along the longitudinal direction (L) and centered on the optically transparent substrate 10 along the lateral direction (A). The passive electrical components 80 may be distributed to both sides of the microcontroller 70, lens 20, and mechanical guard 90 along the lateral direction (A). The microcontroller 70 may be flip-chip mounted to the first major surface 12. The passive electrical components 80 may be mounted to the first major surface using surface mount technology (SMT). The passive electrical components may include, are not limited to, resistors and capacitors. The lens 20 and the mechanical guard 90 may be mounted to the first major surface 12 using an adhesive.

FIG. 3 shows a bottom perspective view of the optical engine 16 depicted in FIG. 1 with all the components mounted to the second major surface 14. The embodiment depicted in FIG. 3 shows an optical engine 16 having four optoelectronic elements 32 and four associated electrical components 34. The four optoelectronic elements include two lasers 50 and two photodetectors 60. In should be appreciated that there may be more or fewer optoelectronic elements 32 and associated electrical components 34. In some embodiments all the optoelectronic elements 32 may be lasers 50. In other embodiments all the optoelectronic elements 32 may be photodetectors. In yet other embodiments, some of the optoelectronic elements 32 may be lasers 50 and some may to photodetectors 60, but the number of lasers 50 may be different than the number of photodetectors 60.

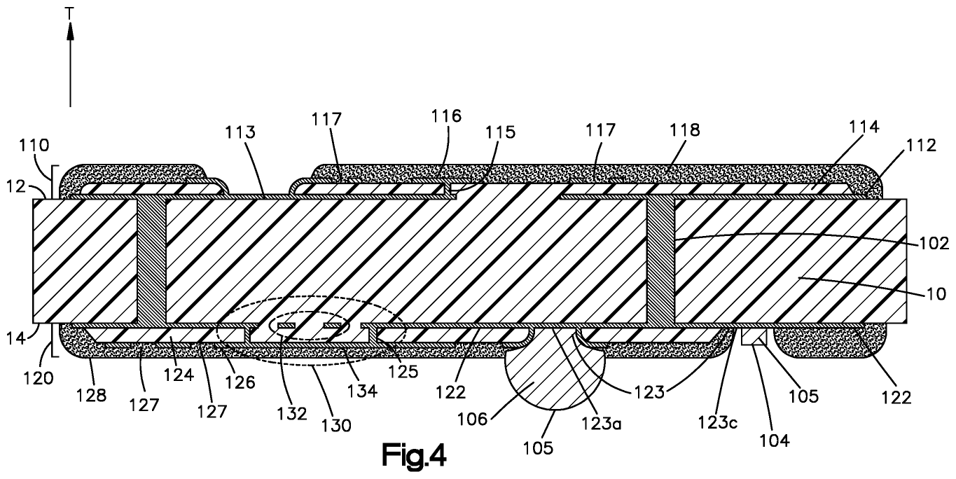

FIG. 4 shows a schematic cross-sectional view of a portion of an optical engine 16 with all electrical components and optoelectronic elements removed. FIG. 4 illustrates some electrical features of the optical engine 10 and does not show any of the optical features, which are described in more detail below. The first major surface 12 of the optically transparent substrate 10 may include a first surface coating layer 110. The first surface coating layer 110 may be a plurality of first surface coating layers comprising alternating metal and dielectric layers. Specifically, the first surface coating layer may comprise first metal surface layer 112, a first surface first dielectric layer 114 disposed on the first surface first metal layer 112, a first surface second metal layer 116 disposed on the first surface first dielectric layer 114, and a first surface second dielectric layer 118 disposed on the first surface second metal layer 116. The first surface first metal layer 112 may be a first surface redistribution layer having a plurality of first surface contact pads 113. The plurality of first surface contact pads 113 may be arranged to accept the microcontroller 70 and the passive electrical components 80 (see FIG. 1). The microcontroller 70 may be electrically connected to the first surface contact pads 113 using flip-chip technology and the passive electrical components 80 may be electrically connected to the first surface contact pads using surface mount technology. The first surface second metal layer 116 may have a plurality of degassing openings 117. The degassing openings 117 may serve no electrical function and may be configured to help release gas that may be produced by chemical reactions in the first surface first dielectric layer 114. Avoiding trapping any residual gases beneath the first surface second metal layer 116 reduces stress and improves the integrity of the first surface coating layer 110.

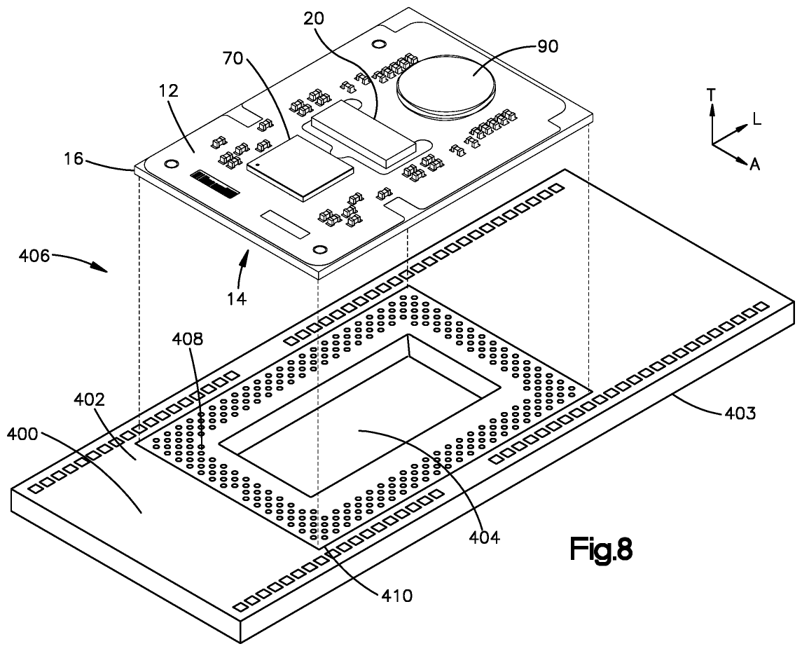

The second major surface 14 may include a second surface coating layer 120. The second surface coating layer 120 can include alternating metal and dielectric layers. Specifically, the second surface coating layer 120 may comprise a second surface first metal layer 122, a second surface first dielectric layer 124 disposed on the second surface first metal layer 122, a second surface second metal layer 126 disposed on the second surface first dielectric layer 124, and a second surface second dielectric layer 128 disposed on the second surface second metal layer 126. The second surface first metal layer 122 may be a second surface redistribution layer having a plurality of second surface contact pads 123. The plurality of second surface contact pads 123 may be arranged to accept the optoelectronic element 32, the associated electrical component 34 (see FIG. 1) and a mounting substrate 400 (see FIG. 8). There may be several types of second surface contact pads 123, such as, but not limited to, a differential pair contact pad 123a, a low-speed contact pad 123b, and a second surface component mounting pad 123c. The optoelectronic element 32 and the associated electrical component 34 may be electrically connected to the second surface component mounting pads 123c using a stud bump 104. The mounting substrate 400 (see FIG. 8) may be electrically connected to the differential pair contact pads 123a and the low-speed contact pad 123b using solder balls 106 that is part of a ball grid array (BGA) of solder balls. Each of the contact pads can attach mechanically and electrically to a respective one of the solder balls. Alternatively, a reflowed solder paste may be used to make the electrical connection instead of a reflowed solder ball. The second surface second metal layer 126 may have a plurality of degassing openings 127. The degassing openings 127 may serve no electrical function and are configured to reduce stresses in the second surface coating layer 120. Stresses in the second surface coating layer 120 may arise from trapped gases originating in the second surface first dielectric layer 124, which may be trapped beneath the second surface second metal layer 126 if the degassing openings 127 were not present.

The second surface coating layer 120 may also include a differential pair coplanar transmission line 130. The differential pair coplanar transmission line 130 may include a differential pair of signal conductors 132 and an electrical ground 134. The differential pair of signal conductors 132 may be formed in the second surface first metal layer 122 and the electrical ground 134 may be formed in the second surface second metal layer 126. A portion of the second surface first metal layer 122 may also be an electrical ground. The second surface first dielectric layer 124 may fill the space between the differential pair of signal conductors 132 and the electrical ground 134 and serve to electrically isolate the differential pair of signal conductors 132 from the electrical ground 134. The differential pair coplanar transmission line 130 may have a characteristic differential impedance between 80 and 100 Ohms. Specifically, the characteristic impedance of the differential pair coplanar transmission line 130 may be approximately 93 Ohms.

With continuing reference to FIG. 4, the first surface first metal layer 112 may be in electrical communication with a second surface first metal layer 122. For instance, the optically transparent substrate 10, and thus the optical engine 16, can include a through electrically conductive via 102 that extends from the first major surface 12 to the second major surface 14, and places the first surface first metal layer 112 in electrical communication with the second surface first metal layer 122. The optical engine 16 can include a plurality of through electrically conductive vias 102 as desired. At least one of the plurality of electrically conductive vias 102 may be hermetically sealed so as to limit or prevent undesirable contaminants that can otherwise propagate through the optically transparent substrate 10.

The first surface first metal layer 112 may also be in electrical communication with the first surface second metal layer 116. For instance, the optically transparent substrate 10, and thus the optical engine 16, can include a first surface via 115 that extends through the first surface first dielectric layer 114 from the first surface first metal layer 112 to the first surface second metal layer 116. Thus, the first surface via 115 electrically connects a portion of the first surface first metal layer 112 with a portion of the first surface second metal layer 116 so that they may in electrical communication with each other. The optically transparent substrate 10, and thus the optical engine 16, can include any number of first surface vias 115 as desired.

Similarly, the second surface first metal layer 122 may be in electrical communication with the second surface second metal layer 126. For instance, the optically transparent substrate 10, and thus the optical engine 16, can include a second surface via 125 that extends through the second surface first dielectric layer 124 from the second surface first metal layer 122 to the second surface second metal layer 126. Thus, the second surface via 125 electrically connects a portion of the second surface first metal layer 122 with a portion of the second surface second metal layer 126 so that the metal layers 122 and 126 may in electrical communication with each other.

It should therefore be appreciated that the microcontroller 70 may be in electrical communication with the associated electrical component 34 (see FIG. 1) through at least one of the through electrically conductive vias 102. For example, power and/or and control signals may pass between the microcontroller 70 and the associated electrical component 34 through at least one of the through electrically conductive vias 102. The optical engine 16 may be arranged such that high-speed electronic signals are not routed through any of the through electrically conductive vias 102.

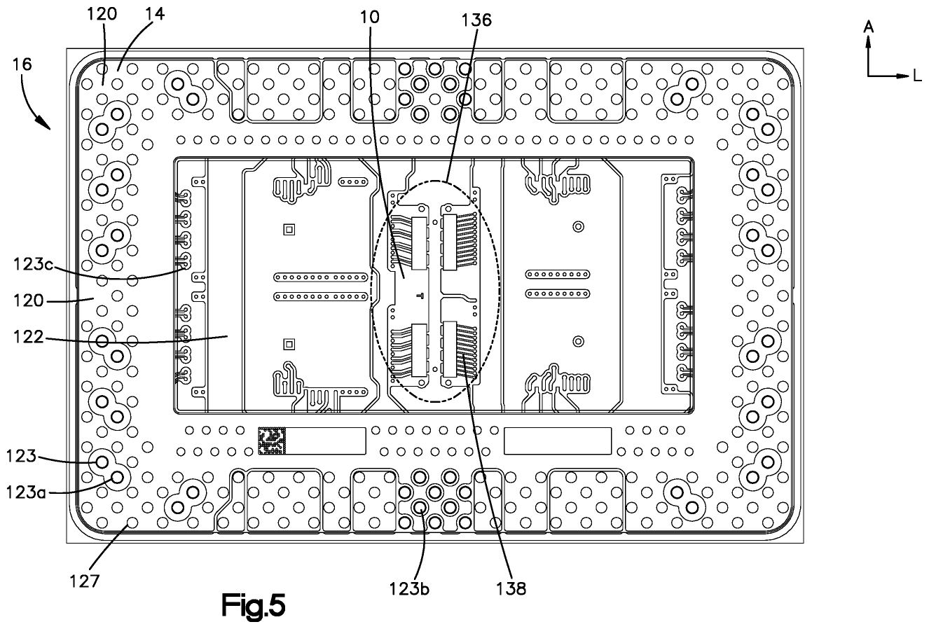

FIG. 5 shows a plan view of the second major surface 14 of the optical engine 16 with the optoelectronic elements 32 and associated electrical components 34 removed. Most of the second major surface 14 is covered by the second surface coating layer 120; however, there are some regions where the underlying optically transparent substrate 10 is visible. In an optoelectronic element mounting region 136 some portion of the optically transparent substrate 10 is exposed so that light delivered to or emitted from the optoelectronic elements 32 may be transmitted through the optically transparent substrate 10 without traveling through the second surface coating layer 120. Electrically conductive traces 138 in the second surface first metal layer 122 may be arranged to transmit high-speed electrical signals between the optoelectronic element 32 and its associated electrical component 34 (not shown in FIG. 5 so underlying traces 138 are visible). The second surface first metal layer 122 may have several different types of second surface contact pads 123. For instance, the contact pads 123 can include differential pair contact pads 123a that provide for the transmission of high-speed signals to be transmitted on and/or off the optical engine 16 within acceptable levels of cross talk. Sixteen (16) pairs of differential pair contact pads 123a are shown in FIG. 5, but any number of differential pair contact pads 123a can be used. The differential pair contact pads 123a may be arranged diagonally with respect to each other, such that a line extending between the individual contact pads in a differential pair of contact pads 123a is not parallel to the longitudinal direction (L) nor the lateral direction (A). To enable low-speed signals, such as power and control signals, to be transmitted on and/or off the optical engine 16, there may be low-speed contact pads 123b. The electrical contact pads 123 can further include second surface component contact pads 123c that provide for both high-speed and low-speed signals to be transmitted to and between components and elements mounted on the second major surface 14 within acceptable levels of crosstalk.

The differential pair coplanar transmission line 130 shown in FIG. 4 may electrically connect the differential pair contact pads 123a with some of the second surface component contact pads 123c. It can be desirable to minimize electrical discontinuities at the differential pair contact pads 123a and the second surface component contact pads 123c where the differential pair coplanar transmission line 130 terminates, for instance to maintain good signal integrity for high-speed signals being transmitted along the differential pair coplanar transmission line 130. The differential pair coplanar transmission line 130 may terminate at a first end at a respective differential pair contact pads 123a and may terminate at a second opposed end at a respective second surface component contact pads 123c. The differential pair contact pads 123a may be larger than the second surface component contact pads 123c. The differential pair contact pads 123a may be arranged to accept a solder ball 106, whereas the second surface component contact pads 123c may be arranged to accept a stud bump 104. The solder ball 106 may have a larger maximum cross-sectional dimension (such as a diameter), and can also be taller than the stud bump 104 along the transverse direction T.

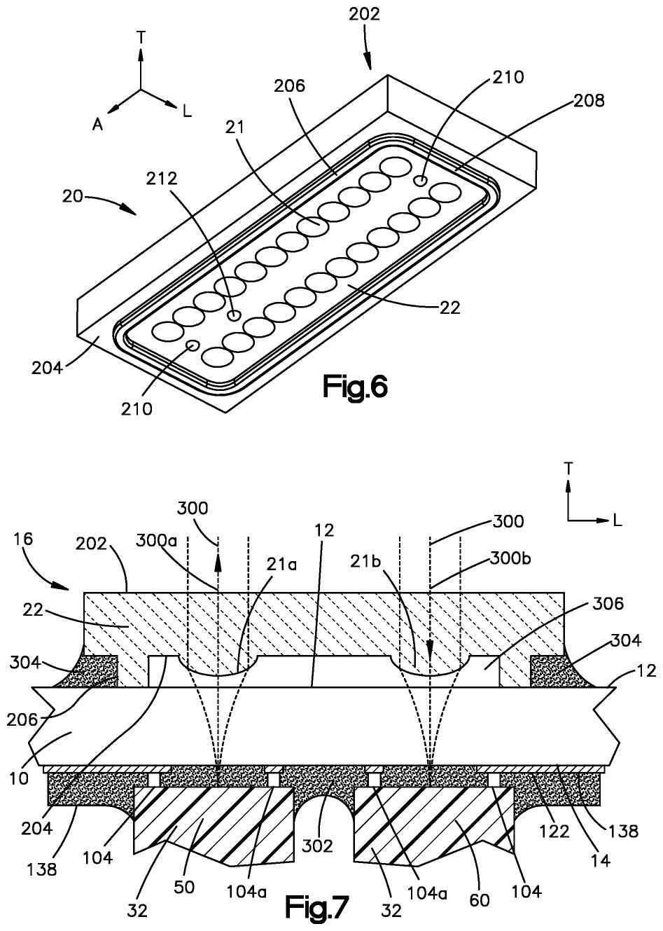

As described above, and referring now to FIG. 6, the optical engine can include the lens 20 which can be configured as a lens array 22. The lens array 22 can include a plurality of individual lenses 21. The lens array 22 may have a top surface 202 and an opposed bottom surface 204 spaced from the top surface 202 in the downward direction. The top surface 202 may be substantially planar. A plurality of individual lenses 21 may be formed on the bottom surface 204 of the lens array 22. The plurality of individual lenses 21 may be arranged in two rows extended along the lateral direction (A), the rows being offset from each other in the longitudinal direction (L). In FIG. 6, the lens array 22 is shown as having twelve (12) lenses in each row for a total of twenty-four (24) individual lenses 21, but any lenses can be included as desired. At least one, up to all, of the individual lenses 21 may be in optical alignment with an active area of an optoelectronic element 32 (see FIG. 7) that emits or detects light. It should be appreciated that some individual lenses 21 may not be in optical alignment with an optoelectronic element 32, so that a single lens array 22 may be used with multiple optoelectronic element arrangements. For example, in some embodiments a central group of the individual lenses 21 (such as four central individual lenses 21) of each row are not utilized. This arrangement would be suitable for an optical engine 16 having sixteen (16) optical channels. The optical channels may be arranged as eight (8) transmit channels and eight (8) receive channels, but the channel arrangement is not so limited. For example, in some embodiments only one of the two rows of individual lenses 21 may be in optical alignment with an optoelectronic element 32. The bottom surface 204 may also include a raised ring 206.

The lens 20 can include a raised ring 106 that extends out from the bottom surface 208 along the transverse direction (T). As shown, the raised ring 106 can extend downward from the bottom surface 208. The raised ring 106 can extend farther in the transverse direction (T) than any portion of the individual lenses 21 extend in the transverse direction (T). Thus, when the lens array 22 is positioned on the first major surface 12 of the optically transparent substrate 10, the bottom surface 208 of the raised ring 206 rests against the optically transparent substrate 10. A seal may be disposed between the raised ring 206 and the major surface 12 forming a sealed enclosed volume that surrounds the individual lenses 21. The enclosed volume may be filled with a gas, such as, but not limited to, air or dry nitrogen. When the raised ring 206 abuts the first major surface 12, the individual lenses 21 may be slightly spaced from the first major surface 12 and may be arranged to either receive or deliver collimated light. If the individual lens 21 is part of an optical receive channel, the individual lens 21 is arranged to focus incoming light into the optoelectronic element 32 configured as a photodetector. If the individual lens 21 is part of an optical transmit channel, the individual lens 21 is arranged to collimate outgoing light emitted by the optoelectronic element 32 configured as a light source. The lens array 22 may also include one or more alignment fiducials 210, such as two alignment fiducials 210 as shown in FIG. 6. The lens array 22 may be aligned with one or more optoelectronic elements 32 with the aid of the alignment fiducials 210. The lens array 22 may also include a labeling feature 212 that enables identification of the lens array 22 so that it may be distinguished from other similar styles of lens arrays.

FIG. 7 is a schematic cross-sectional view of the optical engine 16 in a plane defined by the longitudinal and transverse directions of two optical paths 300 in one example. FIG. 7 shows two optoelectronic elements 32, one being a laser 50 and one being a photodetector 60. A first optical path 300a originates with the laser 50 and is associated with a transmit channel that receives electrical input signals and converts the electrical input signals to optical output signals. A second optical path 300b terminates in the photodetector 60 and is associated with a receive channel that receives optical input signals and converts the optical input signals to electrical output signals. The lens array 22 may be mounted to the first major surface 12 of the optically transparent substrate 10. The lens array 22 may be considered in optical alignment with the optoelectronic elements 32 if the first and second optical paths 300a and 300b terminate or originate in an active area of the respective optoelectronic elements 32. Further, when the lens array 22 is in optical alignment with the optoelectronic elements 32, the first and second optical paths 300a and 300b can be substantially parallel to each other and oriented along the transverse direction (T), which is substantially perpendicular to the major surface 12.

Both optical paths 300a and 300b may be transmitted through the optically transparent substrate 10, an enclosed volume 306 of the lens 20, the lens array 22, and an optically transparent underfill 302. It should be appreciated that an entirety of the optically transparent substrate 10, with the exception of the electrically conductive vias 102 (see FIG. 4) can be optically transparent as described above. Alternatively, the optically transparent substrate 10 can include only a select region or regions that are optically transparent, whereby the optical paths 300a and 300 are transmitted through the select region or regions as they travel through the optically transparent substrate 10. A remainder of the optically transparent substrate 10 can be optically translucent or opaque as desired.

Transmit channel light propagating in optical path 300a may be emitted by the laser 50 along the transverse direction (T). Transmit channel light may be substantially collimated by the collimating lens 21a and leave the lens array 22 propagating substantially along the transverse direction (T). Receive channel light propagating in optical path 300b may be substantially collimated as it enters the lens array 22 along the transverse direction (T). Receive channel light may be focused by the focusing lens 21b on to the photodetector 60. An optical power of the collimating lens 21a and the focusing lens 21b may be substantially the same. An optically transparent underfill 302 may seal the optical paths 300a and 300b from the surrounding environment. The optically transparent underfill 302 can extend along the second major surface 14, surround the stud bumps 104 and dummy stud bumps 104a, and extend to and around respective portions of the optoelectronic elements 32. The dummy stud bump 104a has no electrical functionality, but solely serves a mechanical function. The dummy stud bump 104a may increase the mechanical stability and flatness of the optoelectronic element 32

The enclosed volume 306 surrounds the individual lenses 21, and may be sealed from the surrounding environment using a sealing adhesive 304 disposed at an interface between the lens 200 and the first major surface 12. The sealing adhesive 304 thus helps to form the enclosed volume 306 surrounding the individual lenses 21 and isolates the enclosed volume from the surrounding environment. The enclosed volume 306 may be filled with a gas, such as air or dry nitrogen, or it may be filled with a liquid or gel having a lower index of refractive than the refractive index of the lens array 22. The sealing adhesive 304 may also permanently affix the lens array 22 to the optically transparent substrate 10.

With continuing reference to FIG. 7, the optically transparent substrate 10, and thus the optical engine 16, can include electrically conductive traces 138 disposed on the second major surface 14 of the optically transparent substrate 10. These electrically conductive traces 138 may be part of the second surface first metal layer 122. The electrically conductive traces 138 may provide an electrical connection between the optoelectronic elements 32 and their associated electrical components. Electrical connections between the electrically conductive traces 138 and the laser 50 and photodetector 60 may be made using stud bumps 104 or by any other known interface as desired, such as a flip-chip mounting interface.

An advantage of any of the optical engine 16 is that it can be immersed in any suitable immersion cooling liquid without altering the electrical or optical properties of the optical engine. One example of an immersion cooling liquid is Fluorinert™ coolant commercially available from 3M™ having a principal place of business in St. Paul, MN. During immersion cooling, the optical engine 16 is immersed in the immersion cooling liquid. The optical engine 16 may thus be cooled by immersion cooling in which the optical engine is submerged in the cooling liquid. Heat removal from the optical engine can become increasingly important as the channel density and modulation rates increase. While the optical engine is immersed, the optically transparent underfill 302 and the sealing adhesive 304 can prevent the cooling liquid from entering the optical engine 16 where it could obstruct either of the first and second optical paths 300a and 300b. Thus, the optical engine 16 can be said to be liquid-tight (or watertight) so as to prevent the ingress of the immersion cooling liquid into the optical engine 16 during immersion cooling. A related attribute of the optical engine is that the ability to submerge the optical engine 16 may be achieved without placing the optical engine 16 in a hermetic enclosure. In some examples, the optically transparent underfill 302 and the sealing adhesive 304 can cause the optical engine 16 to be liquid-tight. In some examples, the optical engine 16 can be liquid-tight without being hermetic. In other examples, the enclosed volume 306 that surrounds the individual lenses 21 may be sealed from the surrounding environment using a hermetic sealant disposed at the interface between the lens 200 and the first major surface 12. Further, the optically transparent underfill 302 can be hermetic. Thus, the optical engine 16 can be both liquid-tight and hermetic in some examples. While hermetic isolation of the optical engine 16 does allow optical engine submersion, it can also add undesirable cost, size, and weight to an optoelectronic assembly that includes the optical engine 16.

Aside from allowing immersion cooling, having sealed optical and electrical paths within the optical engine may allow the optical engine to be used in harsh environments, such as salt fog or salt-water spray.

A further advantage of the optical engine 16 is its compact size. As shown in FIG. 1, by placing the microcontroller 70 on the first major surface 12 of the optically transparent substrate 10 and the optoelectronic element(s) 32 on the second major surface 14 of the optically transparent substrate 10, the size of the optically transparent substrate 10 may be reduced compared to systems that have the microcontroller and optoelectronic elements(s) on the same major surface. The smaller size of the optically transparent substrate 10, and thus of the optical engine 16, allows higher channel densities, which can be beneficial in high bandwidth computer and communication systems.

Referring now to FIG. 8, an optoelectronic subassembly 406 can include a mounting substrate 400 and the optical engine 16 that is configured to be mounted to the mounting substrate 400. The mounting substrate 400 can be configured as a printed circuit board (PCB) in some examples. The mounting substrate 400 may have a first major surface 402 to which the optical engine 16 is mounted, and a second major surface 403 opposite the first major surface 402 along the transverse direction (T). In one example, the second major surface 14 of the optically transparent substrate 10 can be mounted to the mounting substrate 400, and in particular to the first major surface 402 of the mounting substrate 400. The optical engine 16 may be mechanically and electrically attached to an attachment area 410 located on a first major surface 402 of the mounting substrate 400. The mounting substrate 400 may have a hole 404 that extends through the first and second first major surfaces 402 and 403. Thus, the hole 404 can be configured as a through hole which receives, and thus provides clearance for, the optoelectronic elements 32 and the associated electrical components 34 (see FIG. 1) when the second major surface 14 of the optical engine 16 is attached to the mounting substrate 400. In other examples, the hole 404 can extend from the first major surface 402 toward the second major surface 403 but terminates above the second major surface 403.

When the optically transparent substrate 10 is mounted to the mounting substrate 400, the optoelectronic element 32 can reside in the hole 404 of the mounting substrate 400. The optical engine 16 may be mechanically mounted and electrically connected to the to the mounting substrate 400 by a solder reflow process. In other words, the solder balls can be reflowed solder balls, which electrically and mechanically connects the second surface contact pads 123 (see FIG. 4) with mounting surface contact pads 408 of the mounting substrate 400, for instance at the first major surface 402. Other or additional attachment mechanisms may be used. Electrical connections between the optical engine 16 and mounting substrate 400 may be arranged such that an impedance of the electrical connection substantially matches an impedance of a transmission line associated with the electrical connection.

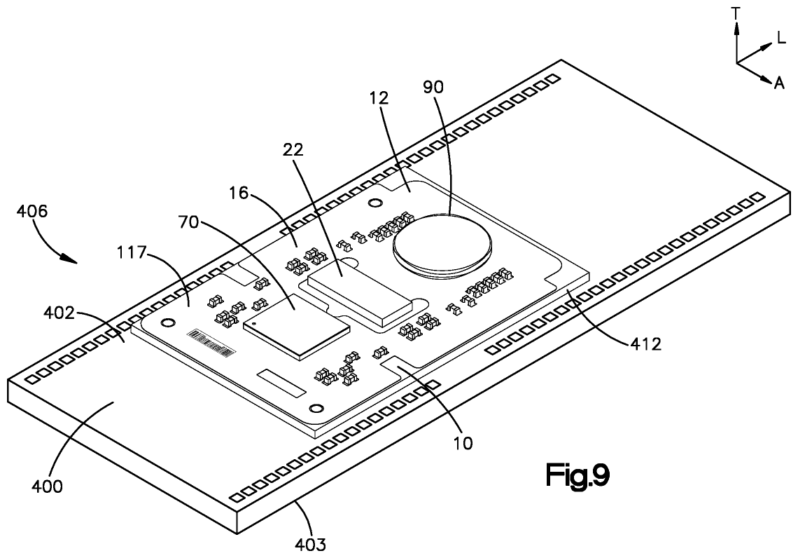

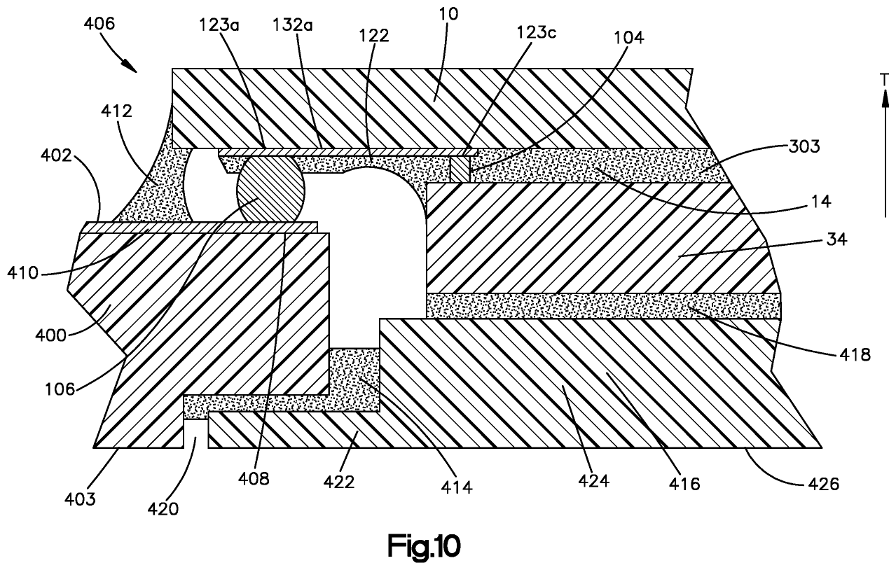

Referring now to FIG. 9, the optoelectronic subassembly 406 can include a seal ring 412 that surrounds a perimeter of the optical engine 16, and in particular a perimeter of the optically transparent substrate 10, and isolates an interface region from the surrounding environment. As will be appreciated from the description below, the interface region can be defined as an interface between the mounting substrate 400 and the optical engine 16. The seal ring 412 can mechanically connect to the first major surface 402 of the mounting substrate 400. The seal ring 412 can be made from any suitable encapsulant as desired. In one example, the seal ring 412 can provide additional mechanical strength to a mounting interface between the optical engine 16 and the mounting substrate 400. Further, the seal ring 412 can prevent or limit environmental contaminates from entering the interface region between the optical engine 16 and the mounting substrate 400. As shown in FIG. 9, the degassing openings 117 may be distributed over regions of the first major surface 12 of the optically transparent substrate 10 which are not covered by the microcontroller 70, passive components 80 or lens array 22. The electrical connections and electrical components of the optoelectronic subassembly 406 may be isolated with respect to fluid flow from the surrounding environment, for example, by applying an encapsulation layer, so that the optoelectronic subassembly 406 may liquid-tight in the manner described above, such that the optoelectronic subassembly 406 can be immersion cooled.

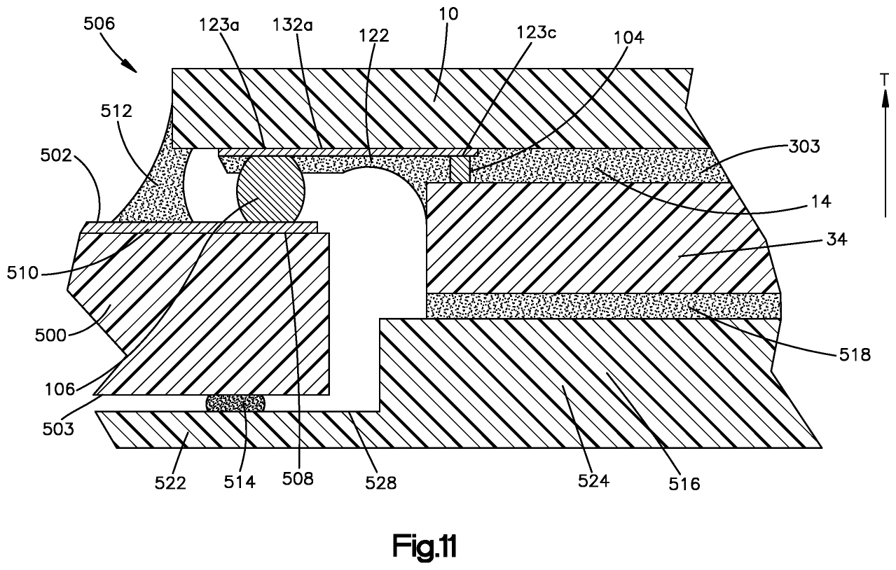

Referring now to FIG. 10, the optoelectronic subassembly 406 can define an interface region between the mounting substrate 400 and the optical engine 16. As previously described relative to FIGS. 8 and 9, the second major surface 14 of the optically transparent substrate 10 may be attached to the first major surface 402 of the mounting substrate 400. The attachment may be through the solder ball 106, which is situated on the mounting substrate contact pad 408 located in the attachment area 410 of the mounting substrate 400. The solder ball 106 may be electrically and mechanically connected to the differential pair contact pad 123a. The differential pair contact pad 123a forms a first end of a conductive trace 132a of a differential pair of signal conductors 132 (see FIG. 4). An opposed second end of the conductive trace 132a of a differential pair of signal conductors 132 is formed by the second surface component contact pads 123c. The differential pair contact pad 123a may have a maximum cross-sectional dimension (such as a diameter) that is larger than that of the second surface component contact pads 123c. The second surface contact 123c may make an electrical and mechanical connection to a stud bump 104, which in turn is mechanically and electrically connected to the associated electrical component 34. The optoelectronic subassembly 406 can include an underfill 303 that may be positioned between the optically transparent substrate 10 and the associated electrical component 34. The underfill 303 may be the same material as the transparent underfill 302 described above or it may be a different underfill material. The seal ring 412 mechanically connects an edge of the optically transparent substrate 10 with the first major surface 403 of the mounting substrate 400. The seal ring 412 is spaced apart from the solder ball 106 and differential pair contact pad 123a so that the seal ring 412 does not significantly impact an impedance of the solder ball 106 electrical connection between the conductive trance of a differential pair of signal conductors 132a and the mounting substrate 400.

As shown in FIG. 10, the optoelectronic subassembly can be devoid of underfill adjacent the differential pair contact pad 123a and solder ball 106, whereas the underfill 303 may be present adjacent the second surface component contact pads 123c and stud bump 104. Thus, the solder balls 106 may be surrounded by a gas, such as air or dry nitrogen, rather than an underfill. Avoiding the use of underfill 303 adjacent the differential pair contact pad 123a and solder ball 106 may be helpful in matching the impedance of the solder ball 106 electrical connection to the impedance of the transmission line 130 associated with the conductive trace 132a. Thus, the solder balls 106 located in the attachment area 410 that are connected to a differential pair contact pad 123a on the second major surface 12 of the optically transparent substrate 10 may be surrounded by a gas to improve the signal integrity of the electrical connection.

As shown in FIG. 10 the optoelectronic subassembly 406 may include a sealing material 414, a heat spreader 416, and a thermal interface material 418. The heat spreader 416 can be positioned such that the associated electrical component 34 is disposed between the optically transparent substrate 10 and the heat spreader 416 with respect to the transverse direction (T). The thermal interface material 418 may be disposed between the associated electrical component 34 and the heat spreader 416. The thermal interface material 418 and heat spreader 416 can dissipate heat generated by the associated electrical component 34. In particular, heat produced by the associated electrical component can be conducted through the thermal interface material 418 and the heat spreader 416, and out the optoelectronic subassembly 406.

In one example, the mounting substrate 400 may include a recess 420 in the second major surface 403. The recess 420 can extend into the second major surface 403 in the upward direction toward the first major surface 402. Further, the recess 420 can extend into an internal edge of the mounting substrate 400 that faces the hole, wherein the recess 420 extends away from the hole along a direction perpendicular to the transverse direction (T). The heat spreader 416 may have a base 422 and a pedestal 424 that extends from a base 422 along the transverse direction (T). For instance, the pedestal 424 can extend up from the base 422. The base can extend out from the pedestal along a direction perpendicular to the transverse direction (T). The base 422 may be situated in the recess 420 of the mounting substrate 400, while the pedestal 424 may extend into the hole 404 of the mounting substrate 400. The thermal interface material 418 may be situated on a top surface of the pedestal 424. A sealing material 414, such as a sealing epoxy, may be situated in the recess 420 and along an edge of the hole 404 and form a water-tight seal between the mounting substrate 400 and the heat spreader 416. A bottom surface 426 of the heat spreader 416 may lie in substantially the same plane as the second major surface 403 of the mounting substrate 400. In other embodiments, the bottom surface 426 of the heat spreader 416 may extend past and thus downward from the second major surface 403 of the mounting substrate 400.

Although not shown in FIG. 10, the heat spreader 416 and thermal interface material 418 may further extend under the optoelectronic element 32 as well as the associated electrical component 34 in the manner described above with respect to the electrical component 34. Thus, the heat spreader 416 and thermal interface material may dissipate heat generated by both the optoelectronic element 32 as well as the associated electrical component 34. The heat spreader 416 can thus define a first region that is disposed adjacent the associated electrical component 34 and substantially dissipates heat from the associated electrical component 34, and a second region that is disposed adjacent the optoelectronic element 32 and substantially dissipates heat from the optoelectronic element 32. A slot can extend into the heat spreader 416 at a location between the first and second regions of the heat spreader 416 to isolate at least a portion such as a majority of the heat that is generated by the optoelectronic element 32 and dissipated by the heat spreader 416 from at least a portion such as a majority of the heat generated in the associated electrical component 34 and dissipated by the heat spreader 416. The slot can extend into a bottom surface of the heat spreader 416 in the upward direction toward the top surface of the heat spreader 416, but can terminate below the top surface of the heat spreader 416. Thus, the slot extends into but not through the heat spreader 416.

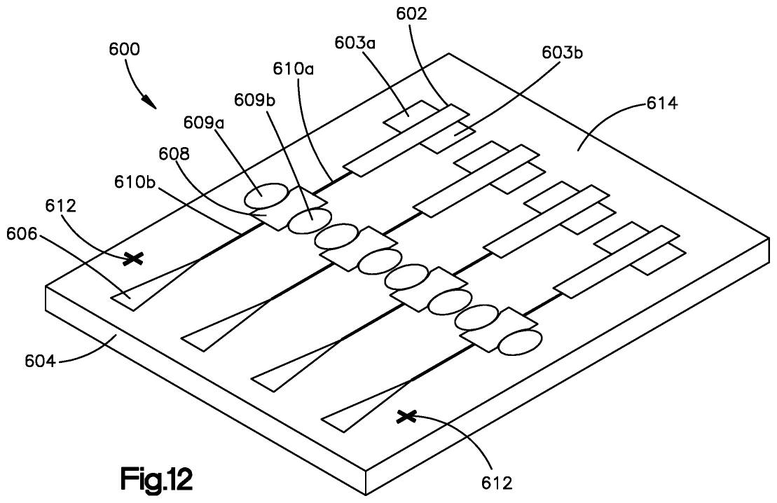

FIG. 11 shows a schematic cross-sectional view of an interface region between a mounting substrate 500 and the optical engine 16 in a portion of an optoelectronic subassembly 506 according to an embodiment of the current invention. The optoelectronic subassembly 506 can be constructed as described with respect to the optoelectronic subassembly 406, with the exception of differences described herein. The optoelectronic subassembly 506 can include the optical engine 16 and a mounting substrate 500 that is constructed as described with respect to the mating substrate 400 of the optoelectronic subassembly 406, with the exception of differences described herein. In the optoelectronic subassembly 506, reference numerals corresponding to like elements of the optoelectronic subassembly 406 have been incremented by 100, with the exception of the optical engine 16 including the optically transparent substrate 10.

One difference between the optoelectronic subassembly 406 and optoelectronic subassembly 506 is that the mounting substrate 500 of the optoelectronic subassembly 506 has no recessed 420. Thus, the edge of the mounting substrate 500 that faces the hole 504 can extend directly to the second major surface 503 of the mounting substrate 500. The base 522 of the heat spreader 516 extends past an edge of the hole 504 (see FIG. 7) of the mounting substrate 500. Thus, the heat spreader base 522 does not extend into the hole in the mounting substrate. Rather, the heat spreader base 522 can face the second major surface 503 of the mounting substrate 500. The optoelectronic subassembly 506 can include the sealing material 514, such as a sealing epoxy, that is disposed in an interface region between the second major surface 503 of the mounting substrate 500 and a top surface 528 of the base 516 and form a water-tight seal between the mounting substrate 500 and the heat spreader 516.

The previously described optoelectronic subassemblies 406 and 506 and optical engine 16 may in incorporated into an optoelectronics assembly as part of an optical interconnect in many ways. For example, the optoelectronic subassembly 406 or optical engine 16 may mounted to an integrated circuit (IC) die package substrate to provide a co-packaged optical connection. Alternatively, the optoelectronic subassembly 406 or optical engine 16 may mounted on a host circuit board adjacent to an IC die package to provide an on-board optical connection. In still other embodiments, the optoelectronic subassembly 406 or optical engine 16 may be incorporated into a front panel mounted interconnect module, such as, but not limited to, a QSFP (Quad Small Form factor Pluggable) or OSFP (Octal Small Form factor Pluggable) style interconnect module.

While the invention has been generally described as using directly modulated VCSELs as a laser source, the invention is not so limited. In other embodiments, the laser source may be a continuous wave (cw) laser whose output is modulated to transmit information. The cw laser may be part of a photonic integrated circuit, such as a silicon or InP chip with integrated lasers, modulators, and waveguides. Photodetectors and associated electrical components may also be included as part of the integrated photonic circuit. The photonic integrated circuit may be attached to the second major surface 14 of the optically transparent substrate 10 in a manner similar to that previously described for the optoelectronic element 32. Light may enter and/or exit the photonic integrated circuit using a surface grating coupler or a reflective mirror that redirects light out of or into the waveguides of the integrated photonic circuit.

FIG. 12 shows a perspective view of an exemplary photonic integrated circuit 600 that can be used as an optoelectronic element 32 in an optical engine 16 (see FIG. 1) according to an embodiment of the current invention. The photonic integrated circuit 600 can be configured to receive at least one input electrical signal from an electrical component, convert the electrical signal to an optical signal that corresponds to the input electrical signal, and output the optical signal. The photonic integrated circuit 600 may include a silicon substrate 604. Optical waveguides 610a and 610b, a one-dimensional grating coupler 606, and a modulator 608 may be formed on a top surface 614 of the silicon substrate 604. A laser 602 may be formed on or permanently attached to the top surface 614 of the silicon substrate 604. The laser 602 may be a distribute feedback (DFB) laser formed on an InP substrate that is configured to lase on both a single transverse mode as well as a single longitudinal mode. An output of the laser 602 is coupled into the waveguide 610. The laser output is modulated in the modulator 608. The modulator 608 can make many forms, including, but not limited to, a Mach-Zehnder modulator, a micro-ring modulator, or an electro-absorption modulator. An output of the modulator 608 may be coupled into an optical waveguide 610b, which is arranged to transmit the modulator output to the one-dimensional grating coupler 606. The one-dimensional grating coupler 606 is arranged to couple light out of the waveguide 610b in a direction generally perpendicular to the top surface 614. Light transmitted out of the grating coupler 606 may then be transmitted through an optically transparent substrate as previously described in regard to a VCSEL based optoelectronic element. A plurality of alignment marks 612 may also be located on the top surface 614 of the silicon substrate. The alignment marks 612 help to align the photonic integrated circuit 600 with other optical elements of an optical engine. Alternatively, the single silicon substrate may be replaced by one or more distributed feedback (DFB) lasers or one or more electro-absorption modulated lasers (EML).

The laser 602 may operate in a continuous-wave (cw) manner. Drive current to the laser 602 may be supplied through laser contact pads 603a and 603b. A modulation signal may be applied to the modulator 608 through modulator contact pads 609a and 609b.

There may be a plurality of channels on the photonic integrated circuit 600. FIG. 12 shows the photonic integrated circuit 600 having four channels, but more or fewer channels may be integrated on a single silicon substrate 604.

In one example, the photonic integrated circuit 600 shown in FIG. 12 can have only transmit capabilities and is not capable of receiving an optical signal. An optical engine may include only transmit optoelectronic elements, like photonic integrated circuit 600, or it may include other types of optoelectronic elements, such as an independent photodetector array, that can act as a receiver. Alternatively, a photonic integrated circuit may be fabricated to include both transmit and receive functionality. When the optoelectronic element 32 includes the photonic integrated circuit 600, the associated electrical component including drive electronics separate from the photonic integrated circuit 600 and configured to drive the photonic integrated circuit 600. In particular, the drive electronics can define a light modulation protocol that determines the modulation of the light emitted from the photonic integrated circuit 600. In other examples, the drive electronics can be integrated into the photonic integrated circuit 600. Thus, the optoelectronic element and the associated electrical component can be integrated into a single substrate that can be mounted to the optically transparent substrate 10 in the manner described above.

It should be noted that the illustrations and discussions of the embodiments shown in the figures are for exemplary purposes only, and should not be construed limiting the disclosure. One skilled in the art will appreciate that the present disclosure contemplates various embodiments. Additionally, it should be understood that the concepts described above with the above-described embodiments may be employed alone or in combination with any of the other embodiments described above. It should further be appreciated that the various alternative embodiments described above with respect to one illustrated embodiment can apply to all embodiments as described herein, unless otherwise indicated.

1. An optical engine comprising:
an optically transparent substrate having a first major surface and an opposed second opposed major surface; and
an optoelectronic element configured to emit or receive light through the optically transparent substrate; and
an associated electrical component in electrical communication with the optoelectronic element configured to deliver or receive electrical signals to or from the optoelectronic element,
wherein the first major surface comprises a first surface coating layer, and
wherein the second major surface comprises a second surface coating layer.

2. (canceled)

3. The optical engine as recited in claim 2, wherein associated electrical component comprises a plurality of associated electrical components that are mounted on the first major surface of the optically transparent substrate, and the optoelectronic element is mounted on the second major surface of the optically transparent substrate.

4-11. (canceled)

12. The optical engine as recited in claim 11, wherein the first surface coating layer comprises a first surface first metal layer disposed on the first major surface of the optically transparent substrate, a first surface first dielectric layer disposed on the first surface first metal layer, a first surface second metal layer disposed on the first surface first dielectric layer, and a first surface second dielectric layer disposed on the first surface second metal layer.

13. The optical engine as recited in claim 12, wherein the first surface first metal layer is a first surface redistribution layer that comprises a plurality of first surface contact pads.

14. The optical engine as recited in claim 13, wherein the microcontroller is electrically connected to the first surface contact pads.

15. The optical engine as recited in claim 12, further comprising a first surface via that electrically connects a portion of the first surface first metal layer with a portion of the first surface second metal layer.

16. The optical engine as recited in claim 12, wherein the first surface second metal layer has a plurality of degassing openings that serve no electrical function and are configured to reduce stress in the first surface coating layer.

17. (canceled)

18. The optical engine as recited in claim 1, wherein the second surface coating layer comprises alternating metal and dielectric layers.

19. The optical engine as recited in claim 18, wherein the second surface coating layer comprises a second surface first metal layer, a second surface first dielectric layer situated on the second surface first metal layer, a second surface second metal layer situated on the second surface first dielectric layer, and a second surface second dielectric layer situated on the second surface second metal layer.

20. The optical engine as recited in claim 19, wherein the second surface first metal layer is a second surface redistribution layer that comprises a plurality of second surface contact pads.

21. The optical engine as recited in claim 19, wherein the second surface second metal layer has a plurality of degassing openings that serve no electrical function and are configured to reduce stress in the first surface coating layer.

22. The optical engine as recited in claim 21, wherein the plurality of second surface contact pads comprises differential pair contact pads at a first end of a coplanar transmission line and second surface component contact pads at an opposed second end of the coplanar transmission line.

23. The optical engine as recited in claim 22, wherein the differential pair contact pads are each configured to mechanically and electrically attach to a respective solder ball.

24. The optical engine as recited in claim 22, wherein the second surface component contact pad is configured to mechanically and electrically attach to a stud bump.

25. The optical engine as recited in claim 22, wherein a maximum cross-sectional dimension of the differential pair contact pad is larger than that of the second surface component contact pad.

26. The optical engine as recited in claim 1, further comprising a mechanical guard mounted to the first major surface.

27. The optical engine as recited in claim 26, wherein an uppermost surface of the mechanical guard is spaced from the first major surface in a transverse direction a greater distance than an uppermost surface of any of the passive components, and the first and second major surfaces are opposite each other along the transverse direction.

28-30. (canceled)

31. The optical engine as recited in claim 1, comprising a lens array having a raised ring having a bottom surface and the bottom of surface of the raised ring extends farther in the transverse direction than any portion of the individual lenses.

32. The optical engine as recited in claim 29, wherein the lens array is attached to the first major surface of the optically transparent substrate with a sealing adhesive to form an enclosed volume surrounding the individual lenses.

33. (canceled)

34. The optical engine as recited in claim 1, wherein the optical engine is configured for immersion cooling.

35. The optical engine as recited in claim 1, wherein a mechanical stud bump is used to help mount the optoelectronic element to the second major surface of the optically transparent substrate.

36. The optical engine as recited in claim 1, further comprising a plurality of electrically conductive through vias that extend from the first major surface to the second major surface, wherein at least one of the plurality of electrically conductive through vias is hermetically sealed such that no undesirable contaminants can propagate through the optically transparent substrate.

37-42. (canceled)

43. The optical engine as recited in claim 1, wherein the electrical signals are differential electrical signals that travel at data transfer rates equal to or greater than approximately 56 gigabit per second while producing no more than 6% worst-case, multi-active cross-talk.

44-59. (canceled)

60. The optical engine as recited in claim 16, configured to operate in salt spray or salt fog.

61. The optical engine as recited in claim 1, wherein the optoelectronic element and the electrical component are configured to be mounted on the second major surface of the optically transparent substrate.

62. The optical engine as recited in claim 1, wherein the optoelectronic element is a photonic integrated circuit.

63. The optical engine as recited in claim 62, wherein the photonic integrated circuit has only transmit capabilities.

64. The optical engine as recited in claim 3, wherein the electrical components comprise a microcontroller.
